(19) United States
(12) Patent Application Publication
(10) Pub. No.: US 2025/0349585 A1
(43) Pub. Date: Nov. 13, 2025

(54) APPARATUS FOR TREATING SUBSTRATE

(71) Applicant: SEMES CO., LTD., Cheonan-si (KR)

(72) Inventors: Eun Jung LEE, Seoul (KR); Jun Hyun LIM, Seoul (KR); Hee Jun YOUN, Goyang-si (KR); Hye Bin GWON, Cheonan-si (KR)

(73) Assignee: SEMES CO., LTD., Cheonan-si (KR)

(21) Appl. No.: 19/204,836

(22) Filed: May 12, 2025

(30) Foreign Application Priority Data
May 10, 2024 (KR) 10-2024-0061730

(51) Int. Cl. H01L 21/677; H01L 21/67

(52) U.S. Cl. CPC H01L 21/67718; H01L 21/67173; H01L 21/67207; H01L 21/67706; H01L 21/67742; H01L 21/67778

(57) ABSTRACT

Provided is an apparatus for treating a substrate. The apparatus includes: a load port part for loading and unloading a transfer container that accommodates a plurality of substrates in a horizontal posture; a lot forming part for changing the plurality of substrates in the horizontal posture, which has been unloaded from the transfer container placed on the load port part, from the horizontal posture to a vertical posture; a first process processing unit including a batch treatment bath for batch-treating the plurality of substrates in the vertical posture; an interface part for changing the plurality of substrates in the vertical posture, which has been batch-treated in the first process processing unit, to the horizontal posture; and a second process processing unit including a first processing chamber in which the substrates changed to the horizontal posture in the interface part are treated one by one, in which the lot forming part, the first process processing unit, and the interface part are arranged along a first direction, and the interface part and the first process chamber are arranged along a second direction perpendicular to the first direction.

### CROSS-REFERENCE TO RELATED APPLICATIONS

This application claims priority to and the benefit of Korean Patent Application No. 10-2024-0061730 filed in the Korean Intellectual Prope Office on May 10, 2024, the entire contents of which are incorporated herein by reference.

### TECHNICAL FIELD

The present invention relates to an apparatus for treating a substrate.

### BACKGROUND ART

In order to manufacture a semiconductor device, a desired pattern is formed on a substrate, such as a wafer, through various processes, such as photography, etching, ashing, ion implantation, and thin film deposition. Each process uses various treatment solutions and treatment gas, and generates particles and by-products during the process. In order to remove the thin film, particles, and process by-products on the substrate from the substrate, a liquid treatment process is performed on the substrate before and after each process. Typically, a liquid treatment process involves treating the substrate with chemicals, followed by removing the chemicals from the substrate with a rinse liquid, and then drying the substrate.

A method of treating substrates with a treatment solution, such as chemicals and/or a rinse liquid, includes a batch treatment method in which multiple substrates are treated in a batch in a vertical posture. In a batch treatment method, the substrate treatment is performed by immersing a plurality of substrates in a vertical posture in a batch in a treatment bath containing a chemical or rinse liquid. Since the substrates are immersed in a vertical posture, if the pattern formed on the substrate has a high aspect ratio, a pattern leaning phenomenon may occur in the pattern formed on the substrate during a process such as lifting the substrate from the treatment bath. In addition, when the drying process is not performed within a short time in the state where the plurality of substrates is exposed to the air at once, there is concern that a water mark may be generated on some of the plurality of substrates exposed to the air. On the other hand, in the case of the single-wafer type treatment method in which the substrates are treated one by one, the substrate treatment is performed by supplying a chemical or a rinse liquid to a single substrate rotating in a horizontal posture. In addition, in the single-wafer treatment method, there is less risk of the pattern lining phenomenon described above occurring because the substrate being transferred is in a horizontal posture, and there is less risk of water marks generated because the substrate is treated one by one and the treated substrate is immediately dried or liquid treated. However, in the case of the single-wafer type treating method, the mass productivity of the substrate treatment is low, and the treatment quality between the substrates is relatively non-uniform when compared with the batch type treating method.

In addition, when the substrate is rotated and spin-dried, and when the pattern formed on the substrate has a high aspect ratio, there is concern that a leaning phenomenon in which the pattern formed on the substrate collapses occurs.

### SUMMARY OF THE INVENTION

The present invention has been made in an effort to provide a substrate treating apparatus capable of improving the mass-producibility of substrate treatment.

The present invention has also been made in an effort to provide a substrate treating apparatus capable of changing the posture of a substrate in a state where the substrate is immersed in a treatment solution.

The present invention has also been made in an effort to provide a substrate treating apparatus capable of minimizing the risk of watermarks being generated on a substrate.

The present invention has also been made in an effort to provide a substrate treating apparatus capable of minimizing the occurrence of a lining phenomenon in a pattern formed on a substrate.

The present invention has also been made in an effort to provide a substrate treating apparatus capable of efficiently treating a substrate formed with a pattern having a high aspect ratio.

The present invention has also been made in an effort to provide a substrate treating apparatus capable of improving space utilization by reducing the size of the apparatus.

The objectives of the present disclosure are not limited thereto and other objectives not stated herein may be clearly understood by those skilled in the art from the following description.

An exemplary embodiment of the present invention, an apparatus for treating a substrate, the apparatus comprising: a load port part for loading and unloading a transfer container that accommodates a plurality of substrates in a horizontal posture; a lot forming part for changing the plurality of substrates in the horizontal posture, which has been unloaded from the transfer container placed on the load port part, from the horizontal posture to a vertical posture; a first process processing unit including a batch treatment bath for batch-treating the plurality of substrates in the vertical posture; an interface part for changing the plurality of substrates in the vertical posture, which has been batch-treated in the first process processing unit, to the horizontal posture; and a second process processing unit including a first processing chamber in which the substrates changed to the horizontal posture in the interface part are treated one by one, wherein the lot forming part, the first process processing unit, and the interface part are arranged along a first direction, and the interface part and the first process chamber are arranged along a second direction perpendicular to the first direction.

According to the exemplary embodiment of the present invention, the interface part includes: a posture changing robot for changing a posture of the substrate between the vertical posture and the horizontal posture; and a posture change treatment bath having a receiving space in which the substrate is received and the posture change takes place, and the posture change treatment bath includes: a support area for supporting the substrate in the vertical posture; a receiving space having a posture change area where the substrate rotates; and a support member positioned in the support area and supporting the substrate, the support area and the batch treatment bath are arranged along the first direction, and the support area and the posture change area may be arrange along the second direction.

According to the exemplary embodiment of the present invention, the interface part, the posture change occurs while the substrate may be immerse in a treatment solution.

According to the exemplary embodiment of the present invention, the posture changing robot may be configured to directly transfer the substrate from the interface part to the first process chamber.

According to the exemplary embodiment of the present invention, the first process processing unit further includes a first transfer robot provided for transferring the substrate between the lot forming part, the batch treatment bath, and the posture change treatment bath, and the first transfer robot may be movably provided along the first direction.

According to the exemplary embodiment of the present invention, the first process chamber may be a liquid treating chamber.

According to the exemplary embodiment of the present invention, the second process processing unit further includes a drying chamber, and the liquid treating chamber and the drying chamber may be arrange sequentially along the second direction.

According to the exemplary embodiment of the present invention, the second process processing unit further includes a second transfer robot provided for transferring the substrate between the liquid treating chamber, the drying chamber, and the load port part, the second transfer robot is movably provided along the second direction, the load port part, the second transfer robot, and the liquid treating chamber are arranged in a direction parallel to the first direction, and the load port part and the lot forming part may be arrange in a direction parallel to the second direction.

According to the exemplary embodiment of the present invention, the second process processing unit further includes: a drying chamber; and a second transfer robot provided for transferring the substrate between the liquid treating chamber, the drying chamber, and the load port part, the second transfer robot is configured to be movable along the first direction, the load port part, the drying chamber, and the liquid treating chamber are arranged in a direction parallel to the first direction, and the load port part and the lot forming part may be arrange in a direction parallel to the first direction.

According to the exemplary embodiment of the present invention, the second process processing unit is provided with the plurality of the batch treatment baths, the batch treatment bath includes: a first treatment bath; and a second treatment bath, the first treatment bath and the second treatment bath are arranged along the first direction, and the interface part may be locate between the first treatment bath and the second treatment bath.

According to the exemplary embodiment of the present invention, the apparatus may further include a controller, wherein the controller controls the substrate to sequentially perform: a substrate loading operation of loading an untreated substrate into the load port part; a batch-treating operation of treating the substrate in the vertical posture in the first process processing unit; a posture changing operation of changing a posture of the substrate from the vertical posture to the horizontal posture in the interface part; a single treating operation for processing each substrate individually in the horizontal posture one by one in the second process processing unit; and a substrate unloading operation of unloading the substrate from the load port part after the single treatment may be completed.

An exemplary embodiment of the present invention, an apparatus for treating a substrate, the apparatus comprising: a load port part for loading and unloading a transfer container that accommodates a plurality of substrates in a horizontal posture; a lot forming part for changing the plurality of substrates in the horizontal posture, which has been unloaded from the transfer container placed on the load port part, from the horizontal posture to a vertical posture; a first process processing unit including a batch treatment bath for batch-treating the plurality of substrates in the vertical posture; an interface part for changing the plurality of substrates in the vertical posture, which has been batch-treated in the first process processing unit, to the horizontal posture; and a second process processing unit including a liquid treating chamber for liquid treating the substrates, which have been changed to the horizontal posture in the interface part, one by one, and a drying chamber for drying the substrates one by one; wherein the lot forming part, the first process processing unit, and the interface part are arranged along a first direction, and the interface part and the liquid treating chamber are arranged along a second direction perpendicular to the first direction, the interface part includes: a posture changing robot for changing a posture of the substrate between the vertical posture and the horizontal posture; and a posture change treatment bath having a receiving space in which the substrate is received and the posture change takes place, and the posture change treatment bath includes: a support area for supporting the substrate in the vertical posture; a receiving space having a posture change area where the substrate rotates; and a support member positioned in the support area and supporting the substrate, the support area and the batch treatment bath are arranged along the first direction, and the support area and the posture changing area are arranged along the second direction, the posture changing robot is configured to directly transfer the substrate from the interface part to the liquid treating chamber, and the posture change occurs while the substrate may be immerse in a treatment solution.

According to the exemplary embodiment of the present invention, the first process processing unit further includes a first transfer robot provided for transferring the substrate between the lot forming part, the batch treatment bath, and the posture change treatment bath, and the first transfer robot may be movably provided along a first direction.

According to the exemplary embodiment of the present invention, the liquid treating chamber and the drying chamber may arrange sequentially along the second direction.

According to the exemplary embodiment of the present invention, the second process processing unit further includes a second transfer robot provided for transferring the substrate between the liquid treating chamber, the drying chamber, and the load port part, the second transfer robot is movably provided along the second direction, the load port part, the second transfer robot, and the liquid treating chamber are arranged in a direction parallel to the first direction, and the load port part and the lot forming part may arrange in a direction parallel to the second direction.

According to the exemplary embodiment of the present invention, the second process processing unit further includes a second transfer robot provided for transferring the substrate between the liquid treating chamber, the drying chamber, and the load port part, the second transfer robot is configured to be movable along the first direction, the load port part, the drying chamber, and the liquid treating chamber are arranged in a direction parallel to the first direction, and the load port part and the lot forming part may be arrange in a direction parallel to the first direction.

According to the exemplary embodiment of the present invention, the second process processing unit is provided with the plurality of the batch treatment baths, the batch treatment bath includes: a first treatment bath; and a second treatment bath, the first treatment bath and the second treatment bath are arranged along the first direction, and the interface part may be locate between the first treatment bath and the second treatment bath.

An exemplary embodiment of the present invention, an apparatus for treating a substrate, the apparatus comprising: a load port part for loading and unloading a transfer container that accommodates a plurality of substrates in a horizontal posture; a lot forming part for changing the plurality of substrates in the horizontal posture, which has been unloaded from the transfer container placed on the load port part, from the horizontal posture to a vertical posture; a first process processing unit including a batch treatment bath for batch-treating the plurality of substrates in the vertical posture; an interface part for changing the plurality of substrates in the vertical posture, which has been batch-treated in the first processing unit, to the horizontal posture; and a second process processing unit including a liquid treating chamber for liquid treating the substrates, which have been changed to the horizontal posture in the interface part, one by one, and a drying chamber for drying the substrates one by one; wherein the lot forming part, the first process processing unit, and the interface part are arranged along a first direction, and the interface part and the liquid treating chamber are arranged along a second direction perpendicular to the first direction, the interface part includes: a posture changing robot for changing a posture of the substrate between the vertical posture and the horizontal posture; and a posture change treatment bath having a receiving space in which the substrate is received and the posture change takes place, and the posture change treatment bath includes: a support area for supporting the substrate in the vertical posture; a receiving space having a posture change area where the substrate rotates; and a support member positioned in the support area and supporting the substrate, the support area and the batch treatment bath are arranged along the first direction, and the support area and the posture changing area are arranged along the second direction, the posture changing robot is configured to directly transfer the substrate from the interface part to the liquid treating chamber, and the posture change occurs while the substrate is immersed in the treatment solution, the batch treatment baths are provided in plurality, the first process processing unit further includes: a batch treatment bath transfer unit provided for transferring a substrate between the batch treatment baths; and a first transfer robot provided for transferring the substrate between the lot forming part, the batch treatment bath, and the posture change treatment bath, and the first transfer robot may be movably provided along a first direction.

According to the exemplary embodiment of the present invention, the second process processing part further includes a second transfer robot provided for transferring the substrate between the liquid treating chamber, the drying chamber, and the load port part, the second transfer robot is movably provided along the second direction, the load port part, the second transfer robot, and the liquid treating chamber are arranged in a direction parallel to the first direction, and the load port part and the lot forming part are arranged in a direction parallel to the second direction, and the liquid treating chamber and the drying chamber may be arrange sequentially along the second direction.

According to the exemplary embodiment of the present invention, the second process processing part further includes a second transfer robot provided for transferring the substrate between the liquid treating chamber, the drying chamber, and the load port part, the second transfer robot is configured to be movable along the first direction, the load port part, the drying chamber, and the liquid treating chamber are arranged in a direction parallel to the first direction, and the load port part and the lot forming part are arranged in a direction parallel to the first direction, the batch treatment bath includes: a first treatment bath; and a second treatment bath, the first treatment bath and the second treatment bath are arranged along the first direction, and the interface part is located between the first treatment bath and the second treatment bath.

According to the exemplary embodiment of the present invention, the mass producibility of substrate processing may be improved.

Furthermore, according to the exemplary embodiment of the present invention, the substrate may be efficiently liquid treated.

Further, according to the exemplary embodiment of the invention, the posture of the substrate may be changed in a state where the substrate is immersed in the treatment solution.

Furthermore, according to the exemplary embodiment of the present invention, the risk of water marks on the substrate may be minimized.

Furthermore, according to the exemplary embodiment of the present invention, the risk of leaning phenomenon occurring in the pattern formed on the substrate may be minimized.

Furthermore, according to the exemplary embodiment of the present invention, a substrate formed with a pattern having a high aspect ratio may be treated efficiently.

Furthermore, according to the exemplary embodiment of the present invention, the size of the apparatus may be reduced to improve space utilization.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a schematic view of a substrate treating apparatus according to an exemplary embodiment of the present invention when viewed from above.

FIG. 2 is a diagram schematically illustrating the structure of a posture change treatment bath of FIG. 1.

FIG. 3 is a diagram schematically illustrating an appearance of a posture changing robot of FIG. 1.

FIG. 4 is a diagram illustrating a substrate treating apparatus provided in a liquid treating chamber of FIG. 1.

FIG. 5 is a diagram illustrating a view of the substrate treating apparatus provided in a drying chamber of FIG. 1.

FIG. 6 is a diagram schematically illustrating a substrate treating apparatus according to another exemplary embodiment of the present invention viewed from the top.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In addition, components that transfer a substrate W described below, for example, the transfer units or transfer robots, may be referred to as transfer modules.

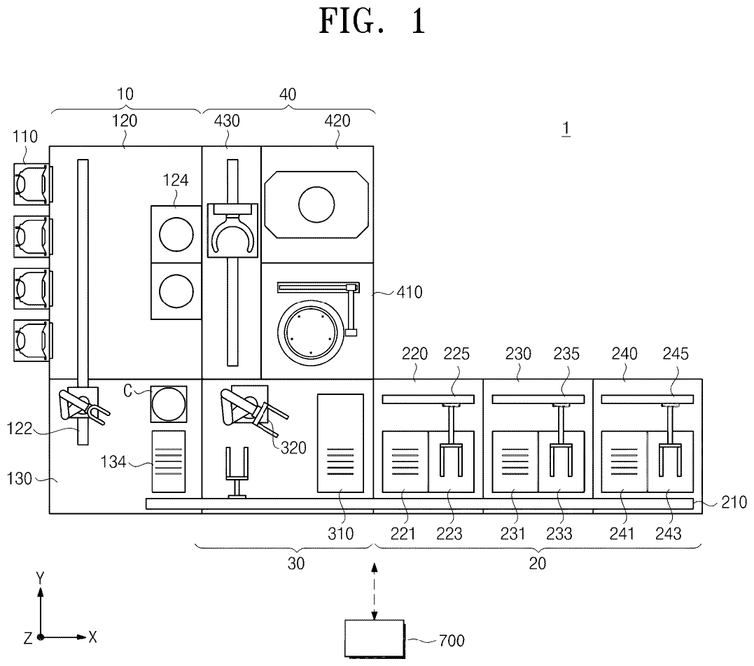

In the following, exemplary embodiments of the present invention will be described with reference to FIGS. 1 to 6.

FIG. 1 is a schematic view of a substrate treating apparatus according to an exemplary embodiment of the present invention when viewed from above.

Referring to FIG. 1, a substrate treating apparatus 1 according to an exemplary embodiment of the present invention may include an index module 10, a first process processing unit 20, an interface part 30, a second process processing unit 40, and a controller 700. The index module 10, the interface part 30, and the first process processing unit 20 may be arranged along a first direction X when viewed from above. Hereinafter, when viewed from above, a direction perpendicular to the first direction X is referred to as a second direction Y, and a direction perpendicular to the first direction X and the second direction Y is referred to as a third direction Z.

The index module 10 may include a load port unit 110, a load port part 120, and a lot forming part 130.

The load port unit 110 may include at least one or more load ports. The load ports of the load port unit 110 may include a transfer container F in which the substrate W is stored. The plurality of substrates W may be accommodated in the transfer container F. For example, the transfer container F may accommodate 25 sheets of substrates W. The transfer container F may be referred to as a cassette, a pod, or a FOUP. The transfer container F may be loaded to or unloaded from the first load port unit 110 by a container transfer device.

The substrates W accommodated in the transfer container F placed on some load ports among the plurality of load ports may be untreated substrates W. The untreated substrates W may be, for example, substrates W on which no processing has been performed, or substrates W on which liquid treatment is required although some processing has been performed. The substrates W accommodated in the transfer container F that are placed in the load ports of the remaining portion of the plurality of load ports may be substrates W that have been treated in the first process processing unit 20 and the second process processing unit 40. In other words, some of the load ports of the plurality of load ports may perform the role of loading the substrate W requiring treatment, and the remaining load ports of the plurality of load ports may perform the role of unloading the treated substrate W from the substrate treating apparatus 1. For example, referring to FIG. 1, the load port unit 110 may include four load ports, and two of the four load ports may be provided as first load port units for loading untreated substrates W, and the remaining two load ports may be provided as second load port units for unloading treated substrates W. In the present specification, the number of load ports is illustrated herein as four, but the present invention is not limited thereto, and may be provided in various numbers depending on conditions, such as process efficiency or footprint.

The load port part 120 may be coupled to the load port unit 110. The load port part 120 and the load port unit 110 may be arranged along the first direction X. The load port part 120 may include an index robot 122 and a buffer unit 124. The index robot 122 may take out the untreated substrate W or the substrate W required to be treated from the container F seated on the load port unit 110. The index robot 122 may take out the substrate W from the container F and load the substrate W into an accommodation container C provided in the lot forming part 130. The index robot 122 may transfer the treatment-completed substrate W to the container F, which is seated in the load port unit 110. The index robot 122 may transfer the substrate W that has been treated and stored in the buffer unit 124 to the container F that is placed in the load port. The index robot 122 may transfer the treated substrate W to the container F placed in a load port included in the second load port unit of the load port unit 110. The container F may be transferred to the outside of the substrate treating apparatus 1 by an article transport device (e.g., OHT).

The index robot 122 may have a hand for gripping and transferring the substrate W. The index robot 122 may have a plurality of hands, some of the plurality of hands may be used only for unloading the substrate W from the container F and transferring the substrate W to the accommodation container C, and other portions of the plurality of hands may be used only for transferring the treatment-completed substrate W from the buffer unit 124 to the container F. The hand of the index robot 122 may be a single-wafer hand for transferring the substrate W one by one. The hand of the index robot 122 may be provided to be movable in the first direction X, the second direction Y, and the third direction Z. Further, the hand of the index robot 122 may be rotatably provided with the third direction Z as the rotation axis.

The lot forming part 130 may include a storage container C and a posture changing unit 124. The load port part 120 and the lot forming part 130 may be arranged parallel to the second direction Y. The accommodation container C may have a substantially cylindrical shape. The accommodation container C may have an accommodation space therein. A plurality of substrates W may be accommodated in the accommodation space of the accommodation container C. For example, 50 substrates W may be accommodated in the accommodation space of the accommodation container C. The accommodation container C may have a cylindrical shape in which at least two or more of the surfaces of the accommodation container C are open. A support member for supporting/holding the substrate W may be provided in the accommodation space of the accommodation container C.

When the loading of the substrate W unloaded from the transfer container F into the accommodation container C is completed, the accommodation container C may be transferred to the posture changing unit 124 disposed in the lot forming part 130 by a transfer means (not illustrated). The posture changing unit 124 may rotate the accommodation container C. For example, the posture changing unit 124 may rotate the accommodation container C so that the opened portion of the accommodation container C faces the top. When the open portion of the accommodation container C is rotated to face the top, the posture of the substrate W accommodated in the accommodation container C may be changed from a horizontal posture (a posture in which the upper and lower surfaces of the substrate W are horizontal to the ground) to the vertical posture. The horizontal posture may mean a state in which the upper surface of the substrate W (for example, the surface on which the pattern is formed) is parallel to the X-Y plane (that is, the ground), and the vertical posture may mean a state in which the upper surface of the substrate W is parallel to the X-Z plane or the Y-Z plane (that is, a plane perpendicular to the ground).

The first process processing unit 100 may liquid-treat a plurality of substrates W in a batch manner. For example, the first process processing unit 100 may collectively clean the plurality of substrates W in a batch manner. The first process processing unit 20 may simultaneously treat the plurality of substrates W in a vertical posture (a posture in which the upper surface or lower surface of the substrate W is parallel to a direction perpendicular to the ground).

The first process processing unit 20 may include a first transfer robot 210, and batch treatment units 220, 230, and 240.

The first transfer unit 210 may include a rail extending along the first direction X and a hand configured to transfer a plurality of substrates W at once. The first transfer robot 210 may grip the substrates W of which the postures are changed in the posture changing unit 134 and transfer the gripped substrates W to the batch treatment units 220, 230, and 240. For example, the first transfer robot 210 may transfer the substrates W of which the postures have been changed in the posture changing unit 134 to any one processing path selected from the treatment baths 221 to 243 included in the batch treatment units 220, 230, and 240. For example, the first transfer robot 210 may transfer the substrates W of which the postures have been changed in the posture changing unit 134 to a first-one batch treatment bath 221.

The first transfer robot 210 may be configured to transfer the substrate W between the first batch treatment unit 220, the second batch treatment unit 230, and the third batch treatment unit 240 of the batch treatment units 220, 230, and 240. Further, the first transfer robot 210 may be configured to transfer the substrate W between the batch treatment units 220, 230, and 240, and the interface part 30.

In addition, the substrates W of which the postures are changed by the posture changing unit 134 and accommodated in the accommodation container C and the substrates W accommodated in the batch treatment baths of the batch treatment units 220, 230, and 240 may be arranged side by side in the first direction X when viewed from above.

The batch treatment units 220, 230, and 240 may liquid-treat a plurality of substrates W at once. The batch treatment units 220, 230, and 240 may clean a plurality of substrates W at a time by using the treatment solution. In the batch treatment units 220, 230, and 240, a plurality of substrates W may be liquid-treated with the treatment solution at one time. The treatment solution used in the batch treatment units 220, 230, and 240 may be a chemical and/or a rinse liquid. For example, the chemical may be a chemical having a property of a strong acid or a strong base. In addition, the rinse solution may be pure. For example, the chemical may be appropriately selected from chemicals removing Ammonia-Hydrogen Peroxide Mixture (APM), Hydrochloricacid-Hydrogen Peroxide Mixture (HPM), Hydrofluoricacid-Hydrogen Peroxide Mixture (FPM), Diluted Hydrofluoric acid (DHF), Diluted Sulfuric acid Peroxide (DSP), or SiN, a chemical containing phosphoric acid, a chemical containing sulfuric acid, and the like. The rinse liquid may be a liquid containing water. For example, the rinse liquid may be appropriately selected from pure water or ozone water.

The batch treatment units 220, 230, and 240 may include the first batch treatment unit 220, the second batch treatment unit 230, and the third batch treatment unit 240.

The first batch treatment unit 220 may include a first-one batch treatment unit 221, a first-two batch treatment unit 223, and a first batch transfer unit 225. In the first-one batch treatment bath 221, the plurality of substrates W may be liquid-treated simultaneously with a chemical, such as DSP. In the first-two batch treatment bath 223, the plurality of substrates W may be treated simultaneously with a chemical, such as DHF. However, without limitation, the treatment solutions used in the first-one batch treatment bath 221 and the first-two batch treatment bath 223 may be varied to any treatment solutions selected from the treatment solutions described above.

The first batch transfer unit 225 may be configured to transfer the substrate W between the first-one batch treatment bath 221 and the first-two batch treatment bath 223.

The second batch treatment unit 230 may include a second-one batch treatment bath 231, a second-two batch treatment bath 233, and a second batch transfer unit 235.

In the second-one batch treatment bath 231, a plurality of substrates W may be simultaneously liquid-treated with a chemical including phosphoric acid. In the second-two batch treatment bath 233, the plurality of substrates W may be treated simultaneously with a rinse liquid. However, without limitation, the treatment solutions used in the second-one batch treatment bath 231 and the second-two batch treatment bath 233 may be varied to a treatment solution selected from the above-described treatment solutions.

The second batch transfer unit 235 may be configured to transfer the substrate W between the second-one batch treatment bath 231 and the second-two batch treatment bath 233.

The third batch treatment unit 240 may include a third-one batch treatment bath 241, a third-two batch treatment bath 243, and a third-batch transfer unit 245.

In the third-one batch treatment bath 241, the plurality of substrate W may be simultaneously liquid treated with a chemical including phosphoric acid. In the third-two batch treatment bath 243, the plurality of substrates W may be treated simultaneously with a rinse liquid. However, without limitation, the treatment solutions used in the third-one batch treatment bath 241 and the third-two batch treatment bath 243 may be varied to a treatment solution selected from the above-described treatment solutions.

The third batch transfer unit 245 may be configured to transfer the substrate W between the third-one batch treatment bath 241 and the third-two batch treatment bath 243.

The interface part 30 is capable of changing the posture of the substrate W. The interface part 30 may change the substrate W in a vertical posture to a horizontal posture. The interface part 30 may change the posture of the substrate W such that the substrate W treated in the vertical posture in the batch treatment units 220, 230, and 240 may be post-treated in the single-wafer processing chambers 410 and 420, which treat the substrate W for a single sheet of substrate W in the horizontal posture. The interface part 30, the lot forming part 130, and the first process processing unit 20 may be arranged along the first direction. The interface part 30 may be disposed between the lot forming part 130 and the first process processing unit 20.

The interface part 30 may include a posture change treatment bath 310 and a posture changing robot 320. The posture change treatment bath 310 may have a greater width than the batch treatment baths 221 to 243 when viewed from above. For example, the posture change treatment bath 310 may have a greater width in a second direction Y (one direction) than the batch treatment baths 221 to 243 when viewed from above. Alternatively, the posture change treatment bath 310 may have the same width in the first direction X (the other direction) as the batch treatment baths 221 to 243 when viewed from above.

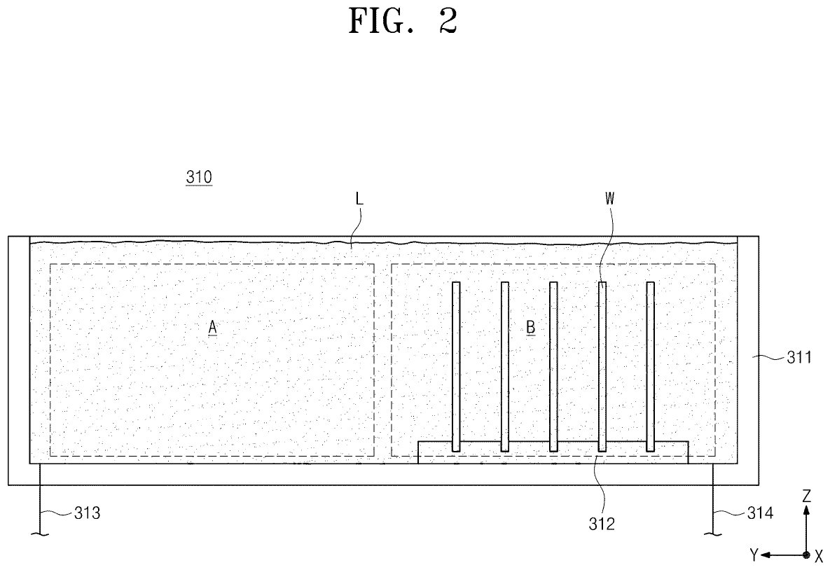

FIG. 2 is a diagram schematically illustrating the structure of a posture change treatment bath of FIG. 1.

Referring to FIG. 2, the posture change treatment bath 310 may include a treatment bath 311, a support member 312, a supply line 313, and a recovery line 314.

The treatment bath 311 may have the shape of a barrel with an open top. The treatment bath 311 may have the shape of a rectangular barrel with an open top. The treatment bath 152 may have receiving spaces A and B in which the treatment solution L may be received (stored) therein. The treatment solution L stored in the treatment bath 311 may be a liquid containing water.

A support member 312 may be disposed in the receiving spaces A and B to support the substrate W. The support members 312 may be configured to support a plurality of substrates W. For example, the support member 312 may be configured to support 50 sheets of substrate W. The support member 312 may include a pair of rod-shaped bodies arranged to face each other, and be formed with a support groove (not illustrated) formed in each body into which the substrate W may be supported.

The supply line 313 may supply the treatment solution L to the receiving spaces A and B. The recovery line 314 may drain the treatment solution L from the receiving spaces A and B. A valve is installed in each of the supply line 313 and the recovery line 314, and based on the liquid surface level of the treatment solution L sensed by a liquid level sensor (not illustrated), the liquid surface level of the treatment solution L supplied to the receiving spaces A and B (that is, the amount of treatment solution L stored in the receiving spaces A and B) may be adjusted to a set level.

In addition, the receiving spaces A and B may include a support area A and a posture change area B. The support area A may be an area in which the support member 312 supports the substrate W. The posture change area B may be an area in which the posture of the substrate W is changed by the posture changing robot 320 to be described later.

Referring again to FIG. 1, the posture changing robot 320 may be disposed on one side of the posture change treatment bath 310. The posture changing robot 320 may include a hand 321 and a joint portion 323. The hand 321 may be coupled to the joint portion 323. The joint portion 323 may be capable of changing the position of the hand 321.

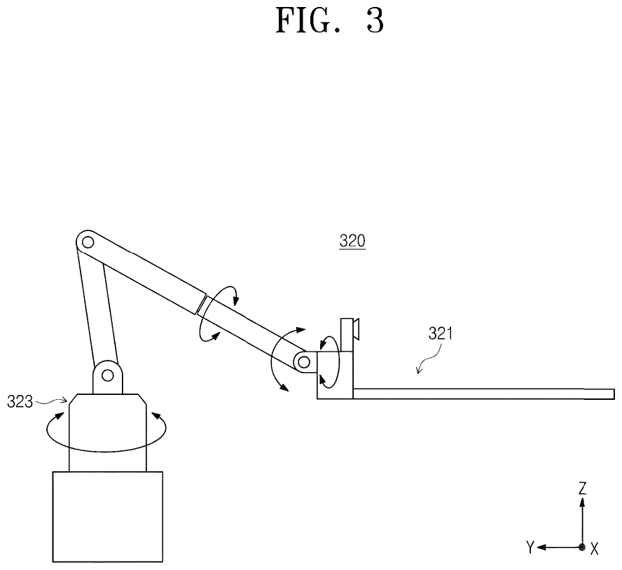

FIG. 3 is a diagram schematically illustrating an appearance of the posture changing robot of FIG. 1. Referring to FIG. 3, the posture changing robot 320 may change the posture of the substrate W from a vertical posture to a horizontal posture in the posture change treatment bath 310, and may transfer the substrate W that has been changed to the horizontal posture to the liquid treating chamber 410 of the second process processing unit 40.

Also, the posture changing robot 156 may be a multi-joint robot. The posture changing robot 320 may be a six-axis multi-joint robot.

The joint portion 323 may be a multi-joint arm formed of at least two or more axes. For example, the joint arm 323 may be a six-axis multi-joint arm. The joint portion 323 may change the position of the hand 321 by moving the hand 321 along at least one of the first direction X, the second direction Y, and the third direction Z. Further, the joint portion 323 may rotate the hand 321 about an axis of one of the first direction X, the second direction Y, and the third direction Z.

Referring again to FIG. 1, the above-described support area A and the batch treatment baths 221 to 243 of the batch treatment units 220, 230, and 240 are arranged along the first direction X, and the support area A and the posture change area B are arranged along the second direction Y.

Furthermore, the substrates W stored in the batch treatment baths 221 to 243 of the batch treatment units 220, 230, and 240 and the substrates W accommodated in the posture change treatment bath 310 of the interface part 30 may each be arranged side by side along the second direction Y when viewed from above. Furthermore, the substrates W accommodated in the batch treatment baths 221 to 243 of the batch treatment units 220, 230, and 240 may be arranged side by side along the second direction Y when viewed from above.

The areas in which the substrates W are accommodated in the batch treatment baths 221 to 243 of the batch treatment units 220, 230, and 240, and the support area A in which the substrates W are accommodated in the posture change treatment bath 310, may be arranged side by side along the first direction X. Due to this arrangement, the movement of the substrate W in the second direction Y may be minimized in a series of processes where the substrate W is transferred from the first process processing unit 20 to the interface part 30, and the posture of the substrate W is changed from a vertical posture to a horizontal posture in the posture change treatment bath 310 of the interface part 30, and the substrate W is transferred to the liquid treating chamber 410 of the second process processing unit 40. Accordingly, the time that the wetting substrate W is exposed to air in the vertical posture may be minimized.

The substrate W is vertically exposed to the air in a wet state when it is transferred by the respective batch transfer units 225, 235, and 245 between the batch treatment baths 221 to 243 of each batch treatment unit 220, 230, and 240.

Then, the substrate W is once again vertically exposed to the air in a wet state when it is transferred by the first transfer robot 210 from the batch treatment baths 221 to 243 of each of the batch treatment units 220, 230, and 240 to the posture change treatment bath 310 of the interface part 30.

The substrate W is then changed in posture in the posture change treatment bath 310 and transferred to the second process processing unit 40, where the posture change of the substrate W is performed while the substrate W is immersed in the treatment solution, and the substrate W is subsequently transferred to a horizontal posture from the second process processing unit 40, so that the vertical exposure of the substrate W to air is limited to the above-described transfer process. In the transfer process in which the substrate W is vertically exposed to the air, the substrate W is lifted in the third direction Z, moved in a direction parallel to the first direction X, and immersed in the treatment solution in the third direction Z again, and there is no movement in the second direction Y, which has the effect of simplifying the transfer path of the substrate W and minimizing the time required for transferring. As the transfer path of the substrate W is simplified and the time required for transferring is minimized, the exposure frequency and exposure time of the substrate W in the wet state to be exposed in a vertical posture in the air are reduced, and accordingly, the pattern leaning phenomenon of the pattern formed on the substrate in the process of lifting the substrate may be minimized.

The second process processing unit 40 may process the substrate W treated in the first process processing unit 20. The second process processing unit 40 may process the substrate W treated in the first process processing unit 20, and may liquid treat or dry treat the substrate W in a single-wafer manner.

The second process processing unit 40 may include the liquid treating chamber 410, the drying chamber 420, and a second transfer robot 430. The liquid treating chamber 410 and the drying chamber 420 may both be referred to as the single-wafer treating chamber.

The liquid treating chamber 410 may be provided in plurality. The liquid treating chambers 410 may be provided in a plurality and may be stacked in an upward and downward direction. The liquid treating chamber 410 may rotate the substrate W in a horizontal posture, and may treat the substrate W by supplying the treatment solution to the rotating substrate W. In the liquid treating chamber 410, the substrate W may be treated one sheet at a time. The treatment solution supplied from the liquid treating chamber 410 may be an organic solvent. For example, the treatment solution supplied from the liquid treating chamber 410 may be isopropyl alcohol (IPA). In the liquid treating chamber 410, the organic solvent may be supplied to the rotating substrate W, and the substrate W may be rotated to dry the substrate W. Alternatively, the liquid treating chamber 410 may supply an organic solvent to the rotating substrate W, and the substrate W may be transferred to the drying chamber 420 described later while the substrate W is still wet in the organic solvent, and the substrate W is dried in the drying chamber 420. The liquid treating chamber 410 will be described in more detail later. The drying chamber 420 may be provided in a plurality. The drying chambers 420 may be provided in a plurality and stacked in an upward and downward direction. In the drying chambers 420, the substrate W may be treated using a supercritical fluid. The drying chamber 420 may be a supercritical chamber for drying a single substrate W in a single-wafer manner. The drying chamber 420 may be a supercritical chamber for drying the substrate W using a supercritical fluid. The drying chamber 420 will be described in more detail later.

The liquid treating chamber 410 and the drying chamber 420 are sequentially disposed along the second direction Y. The liquid treating chamber 410 is disposed closer to the interface part 30 than the drying chamber 420.

The second transfer robot 430 may be disposed at one side of the single-wafer treating chamber. The second transfer robot 430 may unload the substrate W from the liquid treating chamber 410 and transfer the substrate W to the drying chamber 420, or may unload the substrate W from the drying chamber 420 and transfer the substrate W to the buffer unit 124 of the load port part 120.

The controller 700 may control the substrate treating apparatus 1. For example, the controller 700 may control components of the substrate treating apparatus 1. For example, the controller 700 may control the substrate treating apparatus 1 so that the substrate treating apparatus 1 may perform the process of treating the substrate W.

Further, the controller 700 may include a process controller formed of a microprocessor (computer) that executes the control of the substrate treating apparatus 1, a user interface formed of a keyboard in which an operator performs a command input operation or the like in order to manage the substrate treating apparatus 1, a display for visualizing and displaying an operation situation of the substrate treating apparatus 1, and the like, and a storage unit storing a control program for executing the process executed in the substrate treating apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

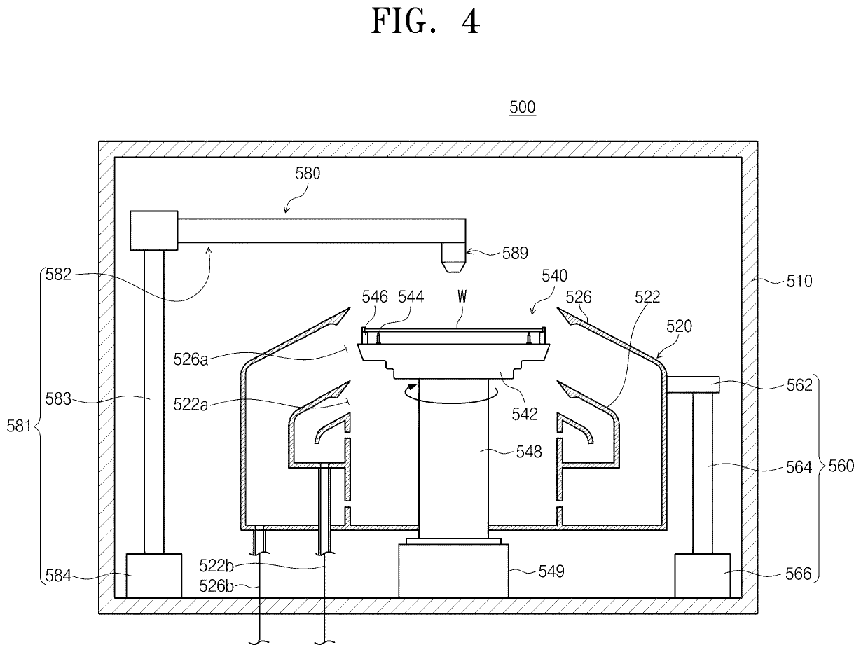

FIG. 4 is a diagram illustrating the substrate treating apparatus provided in the liquid treating chamber of FIG. 1.

Referring to FIG. 4, a substrate treating apparatus 500 provided in the liquid treating chamber 420 may include a housing 510, a treatment container 520, a support unit 540, a lifting unit 560, and a liquid supply unit 580.

The housing 510 has a treatment space 512 therein. The housing 510 may have a barrel shape having a space therein. The treatment container 520, the support unit 540, the lifting unit 560, and the liquid supply unit 580 may be provided in the interior space 512 of the housing 510. The housing 510 may have a rectangular shape when viewed from the front cross-section. However, the present invention is not limited thereto, and the housing 510 may be deformed into various shapes capable of having the treatment space 512.

The treatment container 520 has a barrel shape with an open top. The treatment container 320 includes an inner recovery container 522 and an outer recovery container 526. Each of the recovery containers 522 and 526 recovers different treatment solutions from among the treatment solutions used in the process. The inner recovery container 522 is provided in an annular ring shape surrounding the substrate support unit 540, and the outer recovery container 526 is provided in an annular ring shape surrounding the inner recovery container 526. The interior space 522a of the inner recovery container 522 and the inner recovery container 522 function as a first inlet 522a through which the treatment solution flows into the inner recovery container 522. The space 526a between the inner recovery container 522 and the outer recovery container 526 functions as a second inlet 526a through which the treatment solution flows into the outer recovery container 526. According to an example, each of the inlets 522a and 526a may be located at different heights. The recovery lines 522b and 526b are connected under the bottom of each of the recovery containers 522 and 526. The processing liquids introduced into each of the recovery containers 522 and 526 may be provided to an external processing liquid regeneration system (not illustrated) through the recovery lines 522b and 526b and be reused.

The support unit 540 supports the substrate W in the processing space 512. The support unit 540 supports and rotates the substrate W during the process. The support unit 540 includes a support plate 540, a support pin 542, a chuck pin 544, and rotation drive members 548 and 549.

The support plate 542 is provided in a substantially circular plate shape, and has an upper surface and a lower surface. The lower surface has a smaller diameter than that of the upper surface. That is, the support plate 542 may have a shape of a narrow upper surface and a narrow lower surface. The upper and lower surfaces are positioned so that their central axes coincide with each other. Additionally, the support plate 542 may be provided with a heating means (not illustrated). The heating means provided to the support plate 542 may heat the substrate W placed on the support plate 542. The heating means may generate heat. The heat generated by the heating means may be warm or cold. Heat generated by the heating means may be transferred to the substrate W placed on the support plate 542. In addition, the heat transferred to the substrate W may heat the treatment solution supplied to the substrate W. The heating means may be a heater and/or a cooling coil. However, the present invention is not limited thereto, and the heating means may be variously modified with known devices.

A plurality of support pins 544 is provided. The support pins 544 are disposed to be spaced apart from each other at predetermined intervals on the edge of the upper surface of the support plate 542 and protrude upwardly from the support plate 544. The support pins 544 are arranged to have an annular ring shape as a whole by combination with each other. The support pins 544 support the rear edge of the substrate W so that the substrate W is spaced apart from the upper surface of the support plate 542 by a predetermined distance.

A plurality of chuck pins 546 is provided. The chuck pin 546 is disposed farther from the center of the support plate 542 than the support pin 544. The chuck pin 546 is provided to protrude upward from the upper surface of the support plate 542. The chuck pins 546 support the lateral portions of the substrate W to prevent the substrate W from laterally deviating from its stationary position when the support plate 542 is rotated. The chuck pin 546 is provided to enable linear movement between the outer position and the inner position along the radial direction of the support plate 542. The outer position is a position farther from the center of the support plate 542 compared to the inner position. When the substrate W is being loaded or unloaded onto the support plate 542, the chuck pin 546 is in the outer position, and when the process is being performed on the substrate W, the chuck pin 546 is in the inner position. The inner position is where the chuck pin 546 and the lateral portion of the substrate W are in contact with each other, and the outer position is where the chuck pin 546 and the substrate W are spaced apart.

The rotation drive members 548 and 549 rotate the support plate 542. The support plate 542 is rotatable about a magnetic center axis by the rotation drive members 548 and 549. The rotation drive members 548 and 549 include a support shaft 548 and a drive part 549. An upper end of the support shaft 548 is fixedly coupled to a lower surface of the support plate 542. In one example, the support shaft 548 may be fixedly coupled to a center of the low surface of the support plate 542. The drive part 549 provides driving force to rotate the support shaft 548. The support shaft 548 is rotated by the drive part 549, and the support plate 542 is rotatable with the support shaft 548.

The lifting unit 560 linearly moves the treatment container 520 in the upward and downward direction. As the treatment container 320 moves up and down, the relative height of the treatment container 520 with respect to the support plate 542 changes. The lifting unit 560 lowers the treatment container 520 such that the support plate 542 protrudes over the top of the treatment container 520 when the substrate W is loaded or unloaded onto the support plate 542. Furthermore, when the process is in progress, the height of the treatment container 520 is adjusted to allow the treatment solution to flow into the preset recovery containers 522 and 526 depending on the type of treatment solution supplied to the substrate W. The lifting unit 560 includes a bracket 562, a travelling shaft 564, and a driver 566. The bracket 562 is fixedly installed on the outer wall of the treatment container 520, and the bracket 562 is fixedly coupled to the movement shaft 564, which is moved in the upward and downward direction by the driver 566. Optionally, the lifting unit 560 may move the support plate 542 in the up upward and downward direction.

The liquid supply unit 580 may supply the treatment solution to the substrate W. The processing liquid may be an organic solvent, the aforementioned chemical, or a rinse liquid. The organic solvent may be isopropyl alcohol (IPA) liquid.

The liquid supply unit 580 may include a moving member 581 and a nozzle 589. The moving member 581 moves the nozzle 385 to a process position and a waiting position. The process position is a position where the nozzle 589 faces the substrate W supported by the support unit 540. According to an example, the process position is a position where the treatment solution is discharged to the upper surface of the substrate W. Further, the process position also includes a first supply position and a second supply position. The first supply position may be a position closer to the center of the substrate W than the second supply position, and the second supply position may be a position including an end of the substrate. Optionally, the second supply position may be an area adjacent to the end of the substrate. The waiting position is defined as the position where the nozzle 589 is out of the process position. According to the example, the waiting position may be a position at which the nozzle 589 waits before or after the process processing is completed on the substrate W.

The movement member 581 includes an arm 582, a support shaft 583, and a driver 584. The support shaft 583 is positioned on one side of the treatment container 520. The support shaft 583 is provided to be rotatable by the driver 584. The support shaft 583 is provided to be movable up and down. The arm 582 is coupled to an upper end of the support shaft 583. The arm 582 extends vertically from the support shaft 583. The nozzle 582 is coupled to a distal end of the arm 589. As the support shaft 583 is rotated, the nozzle 589 may swing with the arm 582. The nozzle 589 may be swingably moved to the process position and the standby position. Optionally, the arm 582 may be provided to enable forward and backward movement in its longitudinal direction. A path along which the nozzle 589 moves may coincide with the central axis of the substrate W at the process position when viewed from above.

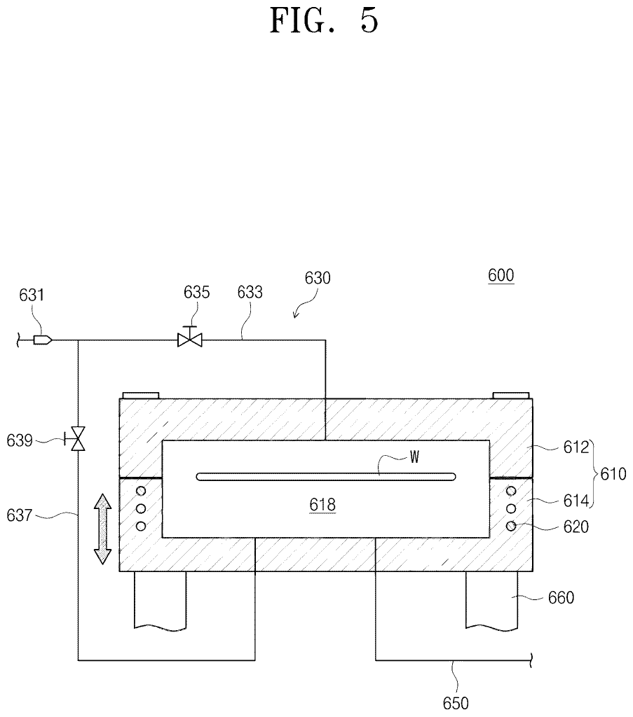

FIG. 5 is a diagram illustrating a view of the substrate treating apparatus provided in a drying chamber of FIG. 1.

Referring to FIG. 5, a substrate treating apparatus 600 provided in the drying chamber 420 may remove the processing liquid remaining on the substrate W by using a drying fluid G in a supercritical state. The drying chamber 420 may be a supercritical chamber in which a processing liquid (for example, a rinse liquid or an organic solvent) remaining on the substrate W is removed by using the supercritical fluid. For example, the substrate treating apparatus 600 provided in the drying chamber 420 may perform a drying process of removing the organic solvent remaining on the substrate W by using carbon dioxide (CO₂) in a supercritical state.

The substrate treating apparatus 600 provided in the drying chamber 420 may include a body 610, a heating member 620, a fluid supply unit 630, a fluid exhaust unit 650, and a lifting member 660. The body 610 may have an interior space 618 in which the substrate W is treated.

The body 610 may provide an interior space 618 in which the substrate W is treated. The body 610 may provide an interior space 618 in which the substrate W is dried by the drying fluid G in a supercritical state.

The body 610 may include an upper body 612 and a lower body 614. The upper body 612 and the lower body 614 may be combined with each other to form the interior space 614. The substrate W may be supported in the interior space 618. For example, the substrate W may be supported by a support member (not illustrated) in the interior space 618. The support member may be configured to support the lower surface of the edge region of the substrate W. Any one of the upper body 612 and the lower body 614 may be coupled to the lifting member 660 to move in the vertical direction. For example, the lower body 614 may be coupled to the lifting member 660 to move vertically by the lifting member 660. Accordingly, the interior space 618 of the body 610 may be optionally sealed. In the above-described example, the case where the lower body 614 is coupled to the lifting member 660 to move in the vertical direction has been described as an example, but the present invention is not limited thereto. For example, the upper body 612 may be coupled to the lifting member 660 to move in the vertical direction.

The heating member 620 may heat the drying fluid G supplied to the interior space 620. The heating member 620 may increase the temperature of the interior space 618 of the body 610 to phase-change the drying fluid G supplied to the interior space 618 into a supercritical state.

In addition, the heating member 620 may increase the temperature of the interior space 618 of the body 610 so that the drying fluid G in the supercritical state supplied to the interior space 618 maintains the supercritical state.

In addition, the heating member 620 may be embedded in the body 610. For example, the heating member 620 may be embedded in any one of the upper body 612 and the lower body 614. For example, the heating member 620 may be provided in the lower body 614. However, the present invention is not limited thereto, and the heating member 620 may be provided at various positions capable of increasing the temperature of the interior space 618. Also, the heating member 620 may be a heater. However, the present invention is not limited thereto, and the heating member 620 may be variously modified into a known device capable of increasing the temperature of the interior space 618.

The fluid supply unit 630 may supply the drying fluid G to the interior space 618 of the body 610. The drying fluid G supplied by the fluid supply unit 630 may include carbon dioxide (CO₂). The fluid supply unit 630 may include a fluid supply source 631, a first supply line 633, a first supply valve 635, a second supply line 637, and a second supply valve 639.

The fluid source 631 may store and/or supply the drying fluid G that is supplied into the interior space 618 of the body 610. The fluid supply source 631 may supply the drying fluid G to the first supply line 633 and/or the second supply line 637. For example, the first supply line 633 may be equipped with the first supply valve 635. In addition, the second supply valve 639 may be installed in the second supply line 637. The first supply valve 635 and the second supply valve 639 may be on/off valves. Depending on the on/off of the first supply valve 635 and the second supply valve 639, the drying fluid G may selectively flow in the first supply line 633 or the second supply line 637.

In the above-described example, the present invention has been described based on the case where the first supply line 633 and the second supply line 637 are connected to one fluid supply source 631 as an example, but the present invention is not limited thereto. For example, a plurality of fluid supply sources 631 may be provided, the first supply line 633 may be connected to any one of the plurality of fluid supply sources 631, and the second supply line 637 may also be connected to another one of the fluid supply sources 631.

Also, the first supply line 633 may be an upper supply line for supplying drying gas from an upper portion of the interior space 618 of the body 610. For example, the first supply line 633 may supply the drying gas to the interior space 618 of the body 610 in a direction from top to bottom. For example, the first supply line 633 may be connected to the upper body 612.

In addition, the second supply line 637 may be a lower supply line for supplying drying gas in the lower portion of the interior space 618 of the body 610. For example, the second supply line 637 may supply the drying gas to the interior space 618 of the body 610 in a direction from bottom to top. For example, the second supply line 637 may be connected to the lower body 614.

The fluid exhaust unit 650 may exhaust the drying fluid G from the interior space 618 of the body 610.

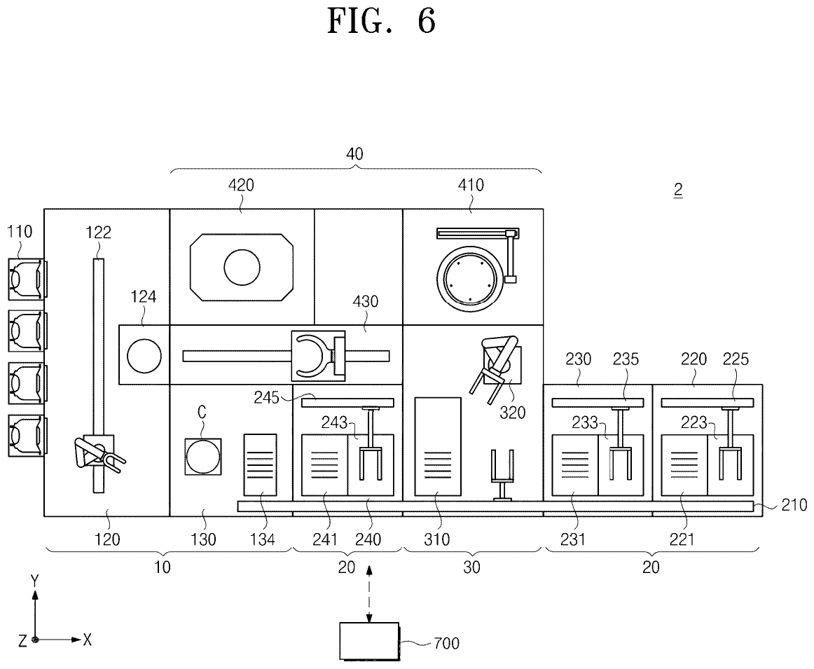

FIG. 6 is a diagram schematically illustrating a substrate treating apparatus according to another exemplary embodiment of the present invention viewed from the top.

The configurations of FIG. 6 that are identical to the configurations of FIG. 1 are denoted by the same reference numerals, and will not be described in detail, and the following discussion will focus on the differences between the arrangement of each configuration of FIG. 6 and FIG. 1.

Referring to FIG. 6, a substrate treating apparatus 2 according to another exemplary embodiment of the present invention may include an index module 10, a first process processing unit 20, an interface part 30, a second process processing unit 40, and a controller 700 that controls the substrate treating apparatus 2. The index module 10, the interface part 30, and the first process processing unit 20 may be arranged along a first direction X when viewed from above.

The index module 10 may include a load port unit 110, a load port part 120, and a lot forming part 130.

The load port part 120 may be coupled to the load port unit 110. The load port part 120 and the load port unit 110 may be arranged along the first direction X.

In FIG. 1, the load port part 120 and the lot forming part 130 are arranged parallel to the second direction Y, whereas in FIG. 6, the load port part 120 and the lot forming part 130 are arranged along the first direction X.

In FIG. 6, a third batch treatment unit 240, an interface part 30, a second batch treatment unit 230, and a first batch treatment unit 220 are arranged along a first direction X such that the interface part 30 is located between the batch treatment containers of the first process processing units 20.

The second process processing unit 40 includes a liquid treating chamber 410, a drying chamber 420, and a second transfer robot 430.

The drying chamber 420 and the liquid treating chamber 410 are arranged sequentially along the first direction X, and the load port part 120, the drying chamber 420, and the liquid treating chamber 410 are arranged in a direction parallel to the first direction X.

The second transfer robot 430 is provided to be movable along the first direction X. The second transfer robot 430 may unload the substrate W from the liquid treating chamber 410 and transfer the substrate W to the drying chamber 420, or may unload the substrate W from the drying chamber 420 and transfer the substrate W to the buffer unit 124 of the load port part 120.

According to the exemplary embodiment of FIG. 6, the substrates W accommodated in the batch treatment baths 221 to 243 of the batch treatment units 220, 230, and 240 and the substrates W accommodated in the posture change treatment bath 310 of the interface part 30 are arranged side by side along the first direction X when viewed from above, in a series of processes in which the substrate W is transferred from the first process processing unit 20 to the interface part 30 and the posture of the substrate W is changed from a vertical posture to a horizontal posture in the posture change treatment bath 310 of the interface part 30 and transferred to the liquid treating chamber 410 of the second process processing unit 40, the time that the substrate W in the wetting state is exposed to the air in the vertical posture may be minimized.

In the transfer process in which the substrate W is vertically exposed to the air, the substrate W is lifted in the third direction Z, moved in a direction parallel to the first direction X, and immersed in the treatment solution in the third direction Z again, and there is no movement in the second direction Y, which has the effect of simplifying the transfer path of the substrate W and minimizing the time required for transferring. As the transfer path of the substrate W is simplified and the time required for transferring is minimized, the frequency and exposure time of the substrate W in the wet state to be exposed in a vertical posture in the air are reduced, and accordingly, the pattern leaning phenomenon of the pattern formed on the substrate in the process of lifting the substrate may be minimized.

In the exemplary embodiment of FIG. 6 described above, the first batch treatment unit 220 and the second batch treatment unit 230 are illustrated as being located on one side of the interface part 30 and the third batch treatment unit 240 is illustrated as being located on the other side of the interface part 30, but the present invention is not limited thereto. The batch treatment units 220, 230, and 240 may be arranged in various combinations that may be arranged in the first direction X with the interface part 30 to simplify the transfer path of the substrate W.

In the exemplary embodiments illustrated and described above, it is illustrated as the index robot 122 is provided in the load port part 120 of the index module 10 to unload untreated or to-be-treated substrates W from the container F seated on the load port unit 110 and to transfer treated substrates W to the container F seated on the load port unit 110, but the present invention is not limited thereto. The index module 10 may include additional index robots in addition to the index robot 122 illustrated, such that one index robot 122 may unload the untreated or to-be-treated substrate W from the container F seated on the load port unit 110, and another index robot may transfer the treated substrate W to the container F seated on the load port unit 110.

According to the above-described exemplary embodiments, as the index module 10 and the load port unit 110 are provided on one side of the substrate treating apparatus 1, 2, and loading and unloading of the substrate W are performed in the same module 10, the size of the apparatus may be reduced to improve space utilization, and the installation of transfer equipment, such as an OHT, may be minimized.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for treating a substrate, the apparatus comprising:
a load port part for loading and unloading a transfer container that accommodates a plurality of substrates in a horizontal posture;
a lot forming part for changing the plurality of substrates in the horizontal posture, which has been unloaded from the transfer container placed on the load port part, from the horizontal posture to a vertical posture;
a first process processing unit including a batch treatment bath for batch-treating the plurality of substrates in the vertical posture;
an interface part for changing the plurality of substrates in the vertical posture, which has been batch-treated in the first process processing unit, to the horizontal posture; and
a second process processing unit including a first processing chamber in which the substrates changed to the horizontal posture in the interface part are treated one by one,
wherein the lot forming part, the first process processing unit, and the interface part are arranged along a first direction, and
the interface part and the first process chamber are arranged along a second direction perpendicular to the first direction.

2. The apparatus of claim 1, wherein the interface part includes:
a posture changing robot for changing a posture of the substrate between the vertical posture and the horizontal posture; and
a posture change treatment bath having a receiving space in which the substrate is received and the posture change takes place, and
the posture change treatment bath includes:
a support area for supporting the substrate in the vertical posture;
a receiving space having a posture change area where the substrate rotates; and
a support member positioned in the support area and supporting the substrate,
the support area and the batch treatment bath are arranged along the first direction, and
the support area and the posture change area are arranged along the second direction.

3. The apparatus of claim 2, wherein in the interface part, the posture change occurs while the substrate is immersed in a treatment solution.

4. The apparatus of claim 2, wherein the posture changing robot is configured to directly transfer the substrate from the interface part to the first process chamber.

5. The apparatus of claim 2, wherein the first process processing unit further includes a first transfer robot provided for transferring the substrate between the lot forming part, the batch treatment bath, and the posture change treatment bath, and
the first transfer robot is movably provided along the first direction.

6. The apparatus of claim 1, wherein the first process chamber is a liquid treating chamber.

7. The apparatus of claim 6, wherein the second process processing unit further includes a drying chamber, and
the liquid treating chamber and the drying chamber are arranged sequentially along the second direction.

8. The apparatus of claim 7, wherein the second process processing unit further includes a second transfer robot provided for transferring the substrate between the liquid treating chamber, the drying chamber, and the load port part,
the second transfer robot is movably provided along the second direction,
the load port part, the second transfer robot, and the liquid treating chamber are arranged in a direction parallel to the first direction, and
the load port part and the lot forming part are arranged in a direction parallel to the second direction.

9. The apparatus of claim 6, wherein the second process processing unit further includes:
a drying chamber; and
a second transfer robot provided for transferring the substrate between the liquid treating chamber, the drying chamber, and the load port part,
the second transfer robot is configured to be movable along the first direction,
the load port part, the drying chamber, and the liquid treating chamber are arranged in a direction parallel to the first direction, and
the load port part and the lot forming part are arranged in a direction parallel to the first direction.

10. The apparatus of claim 9, wherein the second process processing unit is provided with the plurality of the batch treatment baths,
the batch treatment bath includes:
a first treatment bath; and
a second treatment bath,
the first treatment bath and the second treatment bath are arranged along the first direction, and
the interface part is located between the first treatment bath and the second treatment bath.

11. The apparatus of claim 1, further comprising:
a controller,
wherein the controller controls the substrate to sequentially perform:
a substrate loading operation of loading an untreated substrate into the load port part;
a batch-treating operation of treating the substrate in the vertical posture in the first process processing unit;
a posture changing operation of changing a posture of the substrate from the vertical posture to the horizontal posture in the interface part;
a single treating operation for processing each substrate individually in the horizontal posture one by one in the second process processing unit; and
a substrate unloading operation of unloading the substrate from the load port part after the single treatment is completed.

12. An apparatus for treating a substrate, the apparatus comprising:
a load port part for loading and unloading a transfer container that accommodates a plurality of substrates in a horizontal posture;
a lot forming part for changing the plurality of substrates in the horizontal posture, which has been unloaded from the transfer container placed on the load port part, from the horizontal posture to a vertical posture;
a first process processing unit including a batch treatment bath for batch-treating the plurality of substrates in the vertical posture;
an interface part for changing the plurality of substrates in the vertical posture, which has been batch-treated in the first process processing unit, to the horizontal posture; and
a second process processing unit including a liquid treating chamber for liquid treating the substrates, which have been changed to the horizontal posture in the interface part, one by one, and a drying chamber for drying the substrates one by one;
wherein the lot forming part, the first process processing unit, and the interface part are arranged along a first direction, and
the interface part and the liquid treating chamber are arranged along a second direction perpendicular to the first direction,
the interface part includes:
a posture changing robot for changing a posture of the substrate between the vertical posture and the horizontal posture; and
a posture change treatment bath having a receiving space in which the substrate is received and the posture change takes place, and
the posture change treatment bath includes:
a support area for supporting the substrate in the vertical posture;
a receiving space having a posture change area where the substrate rotates; and
a support member positioned in the support area and supporting the substrate,
the support area and the batch treatment bath are arranged along the first direction, and
the support area and the posture changing area are arranged along the second direction,
the posture changing robot is configured to directly transfer the substrate from the interface part to the liquid treating chamber, and
the posture change occurs while the substrate is immersed in a treatment solution.

13. The apparatus of claim 12, wherein the first process processing unit further includes a first transfer robot provided for transferring the substrate between the lot forming part, the batch treatment bath, and the posture change treatment bath, and
the first transfer robot is movably provided along a first direction.

14. The apparatus of claim 13, wherein the liquid treating chamber and the drying chamber are arranged sequentially along the second direction.

15. The apparatus of claim 14, wherein the second process processing unit further includes a second transfer robot provided for transferring the substrate between the liquid treating chamber, the drying chamber, and the load port part,
the second transfer robot is movably provided along the second direction,
the load port part, the second transfer robot, and the liquid treating chamber are arranged in a direction parallel to the first direction, and
the load port part and the lot forming part are arranged in a direction parallel to the second direction.

16. The apparatus of claim 13, wherein the second process processing unit further includes a second transfer robot provided for transferring the substrate between the liquid treating chamber, the drying chamber, and the load port part,
the second transfer robot is configured to be movable along the first direction,
the load port part, the drying chamber, and the liquid treating chamber are arranged in a direction parallel to the first direction, and
the load port part and the lot forming part are arranged in a direction parallel to the first direction.

17. The apparatus of claim 16, wherein the second process processing unit is provided with the plurality of the batch treatment baths,
the batch treatment bath includes:
a first treatment bath; and
a second treatment bath,
the first treatment bath and the second treatment bath are arranged along the first direction, and
the interface part is located between the first treatment bath and the second treatment bath.

18. An apparatus for treating a substrate, the apparatus comprising:
a load port part for loading and unloading a transfer container that accommodates a plurality of substrates in a horizontal posture;
a lot forming part for changing the plurality of substrates in the horizontal posture, which has been unloaded from the transfer container placed on the load port part, from the horizontal posture to a vertical posture;
a first process processing unit including a batch treatment bath for batch-treating the plurality of substrates in the vertical posture;
an interface part for changing the plurality of substrates in the vertical posture, which has been batch-treated in the first processing unit, to the horizontal posture; and
a second process processing unit including a liquid treating chamber for liquid treating the substrates, which have been changed to the horizontal posture in the interface part, one by one, and a drying chamber for drying the substrates one by one;
wherein the lot forming part, the first process processing unit, and the interface part are arranged along a first direction, and
the interface part and the liquid treating chamber are arranged along a second direction perpendicular to the first direction,
the interface part includes:
a posture changing robot for changing a posture of the substrate between the vertical posture and the horizontal posture; and
a posture change treatment bath having a receiving space in which the substrate is received and the posture change takes place, and
the posture change treatment bath includes:
a support area for supporting the substrate in the vertical posture;
a receiving space having a posture change area where the substrate rotates; and
a support member positioned in the support area and supporting the substrate,
the support area and the batch treatment bath are arranged along the first direction, and
the support area and the posture changing area are arranged along the second direction,
the posture changing robot is configured to directly transfer the substrate from the interface part to the liquid treating chamber, and
the posture change occurs while the substrate is immersed in the treatment solution,
the batch treatment baths are provided in plurality,
the first process processing unit further includes:
a batch treatment bath transfer unit provided for transferring a substrate between the batch treatment baths; and
a first transfer robot provided for transferring the substrate between the lot forming part, the batch treatment bath, and the posture change treatment bath, and
the first transfer robot is movably provided along a first direction.

19. The apparatus of claim 18, wherein the second process processing part further includes a second transfer robot provided for transferring the substrate between the liquid treating chamber, the drying chamber, and the load port part,
the second transfer robot is movably provided along the second direction,
the load port part, the second transfer robot, and the liquid treating chamber are arranged in a direction parallel to the first direction, and
the load port part and the lot forming part are arranged in a direction parallel to the second direction, and
the liquid treating chamber and the drying chamber are arranged sequentially along the second direction.

20. The apparatus of claim 18, wherein the second process processing part further includes a second transfer robot provided for transferring the substrate between the liquid treating chamber, the drying chamber, and the load port part,
the second transfer robot is configured to be movable along the first direction,
the load port part, the drying chamber, and the liquid treating chamber are arranged in a direction parallel to the first direction, and
the load port part and the lot forming part are arranged in a direction parallel to the first direction,
the batch treatment bath includes:
a first treatment bath; and
a second treatment bath,
the first treatment bath and the second treatment bath are arranged along the first direction, and
the interface part is located between the first treatment bath and the second treatment bath.
